(19) United States
(12) Patent Application Publication
(10) Pub. No.: US 2023/0241725 A1
(43) Pub. Date: Aug. 3, 2023

(54) SOLDER PASTES AND METHODS OF USING THE SAME

(71) Applicant: Ning-Cheng Lee, New Hartford, NY (US)

(72) Inventor: Ning-Cheng Lee, New Hartford, NY (US)

(21) Appl. No.: 17/578,615

(22) Filed: Jan. 19, 2022

(51) Int. Cl. B23K 35/02; B23K 1/00; B23K 35/26; C22C 13/00; C22C 12/00; C22C 28/00; H05K 3/34

(52) U.S. Cl. CPC B23K 35/025; B23K 1/0016; B23K 35/262; B23K 35/264; C22C 12/00; C22C 13/00; C22C 28/00; H05K 3/3485; B23K 2101/42

(57) ABSTRACT

Solder pastes comprise a high temperature solder powder, a low temperature solder powder and flux. The melting temperature of the low temperature solder powder is lower than that of the high temperature solder powder. The high temperature solder powder and the low temperature solder powder are both capable of wetting upon heating.

### TECHNICAL FIELD

The disclosed technology relates generally to solder pastes and methods of using the same.

### BACKGROUND

System in Package (SiP) is a way to put more than one IC into one package. The major drivers include further advancement in miniaturization, increasing the speed by shortening the signal path, and increasing battery life by reducing the energy dissipation of signal travel. SiP evolved from multichip modules and is becoming more dominant.

While assembly of those ICs continues the adoption of solder paste process, the shrinking gap between neighboring pads inevitably runs into a bottleneck due to the slump of solder paste, particularly hot slump. Whilst sufficient volume of solder paste is needed to assure the yield and reliability of solder joint, the same volume factor also aggravates the slump and consequently the bridging of solder paste during process.

### SUMMARY

Solder pastes and methods of using the solder pastes are disclosed. The solder pastes are of outstanding slump resistance without compromising the paste volume printed, and exhibit acceptable solder joint service temperature.

In one embodiment, a solder paste comprising: a high temperature solder powder; a low temperature solder powder, the melting temperature of which is lower than that of the high temperature solder powder; and flux; wherein the high temperature solder powder and the low temperature solder powder are both capable of wetting upon heating.

In another embodiment, a method comprising: depositing the aforesaid solder paste onto a pad of a printed circuit board; mounting a component on a surface of a printed circuit board with the solder paste.

Other features and aspects of the invention will become apparent from the following detailed description, taken in conjunction with the accompanying drawings, which illustrate, by way of example, the features in accordance with embodiments of the invention. The summary is not intended to limit the scope of the invention, which is defined solely by the claims attached hereto.

### BRIEF DESCRIPTION OF THE DRAWINGS

The technology disclosed herein, in accordance with one or more various embodiments, is described in detail with reference to the included figures. The figures are provided for purposes of illustration only and merely depict example implementations. Furthermore, it should be noted that for clarity and ease of illustration, the elements in the figures have not necessarily been drawn to scale.

FIG. 1 illustrates a comparison of a traditional reflow soldering process and the present reflow soldering process with anti-slump mechanism via powder cluster formation.

FIG. 2 illustrates SAC solder paste printed with 75 µm thick stencil.

FIG. 3 illustrates B4 solder paste printed with 75 µm thick stencil.

FIG. 4 illustrates I4 solder paste printed with 75 µm thick stencil.

FIG. 5 illustrates B16 solder paste printed with 75 µm thick stencil.

FIG. 6 illustrates effect of 58Bi42Sn content on slump rate when tested on pattern 200 µm × 200 µm, with 75 µm thickness.

FIG. 7 illustrates effect of 58Bi42Sn content on slump rate when tested on pattern 150 µm × 150 µm, with 75 µm thickness.

FIG. 8 illustrates effect of 58Bi42Sn content on slump rate when tested on pattern 200 µm × 200 µm, with 50 µm thickness.

FIG. 9 illustrates effect of 58Bi42Sn content on slump rate when tested on pattern 150 µm × 150 µm, with 50 µm thickness.

FIG. 10 illustrates effect of 52In48Sn content on slump rate when tested on pattern 200 µm × 200 µm, with 75 µm thickness.

FIG. 11 illustrates effect of 52In48Sn content on slump rate when tested on pattern 150 µm × 150 µm, with 75 µm thickness.

FIG. 12 illustrates effect of 52In48Sn content on slump rate when tested on pattern 200 µm × 200 µm, with 50 µm thickness.

FIG. 13 illustrates effect of 52In48Sn content on slump rate when tested on pattern 150 µm × 150 µm, with 50 µm thickness.

FIG. 14 illustrates effect of aperture size and the type of low temperature solder powder (alloy type) on slump rate, the alloy type includes 58Bi42Sn (BiSn) and 52In48Sn (InSn).

FIG. 15 illustrates effect of temperature and low temperature solder powder (alloy type) on slump rate, the alloy type includes 58Bi42Sn (BiSn) and 52In48Sn (InSn).

FIG. 16 illustrates effect of stencil patterns and low temperature solder powder (alloy type) on slump rate, the alloy type includes 58Bi42Sn (BiSn) and 52In48Sn (InSn).

FIG. 17 illustrates an operational flow diagram depicting an example of a method with the solder paste.

The figures are not intended to be exhaustive or to limit the invention to the precise form disclosed. It should be understood that the invention can be practiced with modification and alteration, and that the disclosed technology be limited only by the claims and the equivalents thereof.

### DETAILED DESCRIPTION

In the background and the following description, for the purposes of explanation, numerous specific details are set forth in order to provide a thorough understanding of the technology described herein. It will be evident to one skilled in the art, however, that the exemplary embodiments may be practiced without these specific details. In other instances, structures and device are shown in diagram form in order to facilitate description of the exemplary embodiments.

In the prior art technologies, metal powders used for a solder paste may include a solder powder which is capable of wetting and a non-solder powder which is incapable of wetting. For example, 96.5Sn3Ag0.5Cu (SAC305), 58Bi42Sn and 52In48Sn belong to the solder powder, while a copper powder and an iron powder belong to the non-solder powder.

In some prior art technologies, a solder paste with a high temperature solder powder while without a low temperature solder powder may be used. During reflow soldering, a component may be mounted on a surface of a printed circuit board (PCB) with the solder paste based on the capability of wetting of the high temperature solder powder.

In some prior art technologies, a solder paste with a low temperature solder powder and a high temperature non-solder powder may be used. During reflow soldering, a component may be mounted on a surface of a PCB with the solder paste based on the capability of wetting of the low temperature solder powder.

By contrast, in accordance with an embodiment described herein, a solder paste may include a high temperature solder powder, a low temperature solder powder and flux, where the melting temperature of the low temperature solder powder is relatively lower than that of the high temperature solder powder; the high temperature solder powder and the low temperature solder powder are both capable of wetting upon heating.

As described herein, “heating” includes but not limited to reflow soldering. Reflow soldering, reflow or soldering is a process that involves mounting or attaching a component onto a surface of a PCB with the solder paste after the solder paste was deposited onto a pad of the PCB with a stencil. With reflow soldering via the solder paste, a solder joint is formed.

The terms of “high temperature solder powder” and “low temperature solder powder” are relative concepts with respect to each other in terms of their melting temperatures. Therefore, a solder powder may be used as a high temperature solder powder in an implementation while a low temperature solder powder in another implementation.

In implementations, the high temperature solder powder may be 96.5Sn3Ag0.5Cu and the low temperature solder powder may be selected from a group of 58Bi42Sn, 52In48Sn, and combinations thereof.

During prior reflow soldering process, the slump of solder paste occurs, resulting in the bridging of solder paste, which adversely affects the yield and reliability of solder joint. To battle with this challenge, the present solder paste comprises a high temperature solder powder and a low temperature solder powder.

In implementations, a small amount of low temperature solder powder may be introduced into the solder paste with high temperature solder powder.

In particular implementations, a ratio of the mass of the low temperature solder powder to that of the solder paste is not less than 1%, preferably not less than 10%.

FIG. 1 illustrates a comparison of a traditional reflow soldering process and the present reflow soldering process with anti-slump mechanism via powder cluster formation.

As shown in FIG. 1(a), a prior solder paste with a high temperature solder powder while without a low temperature solder powder was used. During reflow soldering, along with the increasing temperature, the high temperature solder powder flowed easily, resulting in the slump of the solder paste.

As shown in FIG. 1(b), a present solder paste with a high temperature solder powder and a low temperature solder powder was used. During reflow soldering, when the heating temperature approached or was not less than the melting temperature of the low temperature solder powder, a “powder cluster” was formed, thus effectively reducing the slump of solder paste. Further heating resulted in complete coalescence of the solder paste without additional slump.

In implementations, when the heating temperature was less than while approached the melting temperature of the low temperature solder powder, the low temperature solder powder was solid-state diffused thereby surrounding the high temperature solder powder, forming a type of powder cluster.

In particular implementations, the solder paste was heated for a first period in a first range of temperature, wherein a temperature within the first range is not less than a predetermined temperature and less than the melting temperature of the low temperature solder powder.

In particular implementations, the predetermined temperature may be less than the melting temperature of the low temperature solder powder and not less than a temperature 15° C. less than the melting temperature of the low temperature solder powder.

In particular implementations, the first period was greater than 5 seconds, preferably greater than 10 seconds, such as 5 minutes.

In implementations, when the heating temperature was not less than the melting temperature of the low temperature solder powder, the low temperature solder powder was melted then wet to surround the high temperature solder powder, forming another type of powder cluster.

In particular implementations, the solder paste was heated for a second period in a second range of temperature, wherein a temperature within the second range was not less than the melting temperature of the low temperature solder powder and less than the melting temperature of the high temperature solder powder.

In particular implementations, the second period may be greater than 5 seconds, preferably greater than 10 seconds, such as 5 minutes.

As shown in table 1 below, a series of samples of solder pastes for anti-slump were prepared, where type 5 58Bi42Sn, type 3 52In48Sn and type 5 SAC305 were used; the ratios of the mass of SAC305, 58Bi42Sn, 52In48Sn and flux to that of the solder paste are shown, respectively.

For these samples, solder volume fraction in solder paste represents a ratio of the volume of both the high temperature solder powder and the low temperature solder powder to that of the solder paste (i.e. metal volume fraction in solder paste), 1^{st} sign of melting of reflowed solder represents a temperature at which the solder paste begins endothermic reaction while the high temperature solder powder is not melted, primary peak temperature represents the highest temperature during reflow soldering at which the high temperature solder powder is melted.

With increasing temperature, the solder paste typically started to weaken near 1^{st} sign of melting of reflowed solder. Therefore, the melting range of the reflowed samples was represented by examining the 1^{st} sign of melting and the primary peak temperature of the reflowed solder, with results listed in table 1.

TABLE 1

| Sample | 96.5Sn3 Ag0.5Cu (density 7.40 g/cm3) | 58Bi42Sn (density 8.56 g/cm3) | 52In48Sn (density 7.3 g/cm3) | Flux (density 1.00 g/cm3) | Solder volume fraction in solder paste (calculated) | 1^{st} sign of melting of reflowed solder (°C) | Primary peak temperature of reflowed solder (°C) |
|---|---|---|---|---|---|---|---|
| SAC | 82% | 0 | 0 | 18% | 0.381 | 217 | 219.9 |
| B2 | 78.31% | 3.69% | 0 | 18% | 0.380 | 200 | 216.7 |
| B4 | 74.63% | 7.37% | 0 | 18% | 0.379 | 194 | 211.9 |
| B8 | 67.3% | 14.7% | 0 | 18% | 0.378 | 177 | 205.3 |
| B12 | 59.9% | 22.1% | 0 | 18% | 0.376 | 137 | 199.8 |
| B16 | 52.5% | 29.5% | 0 | 18% | 0.375 | 137 | 192.6 |
| BiSn | 0 | 82% | 0 | 18% | 0.347 | 138 | 141.2 |
| I2 | 78.31% | 0 | 3.69% | 18% | 0.381 | 207 | 216.7 |
| I4 | 74.63% | 0 | 7.37% | 18% | 0.381 | 203 | 211.1 |
| I8 | 67.3% | 0 | 14.7% | 18% | 0.381 | 189 | 203.6 |
| I12 | 59.9% | 0 | 22.1% | 18% | 0.381 | 113 | 200.6 |
| I16 | 52.5% | 0 | 29.5% | 18% | 0.381 | 114 | 192.9 |
| InSn | 0 | 0 | 82% | 18% | 0.381 | 118 | 120.9 |

As shown in table 2 below, some stencil patterns were used for printing solder paste.

TABLE 2

| | | | |
|---|---|---|---|
| Aperture | Arrangement | Spacing | Thickness |
| 150 µm × 150 µm | 10 × 10, 5 sets in a row | 90 µm | 50 µm |
| 150 µm × 150 µm | 10 × 10, 5 sets in a row | 90 µm | 75 µm |
| 200 µm × 200 µm | 10 × 10, 5 sets in a row | 100 µm | 50 µm |
| 200 µm × 200 µm | 10 × 10, 5 sets in a row | 100 µm | 75 µm |

Each solder paste was printed onto ceramic substrate, three prints each solder paste. For each print, a glass slide used as an electric or electronic component contained in a PCB was gently placed on the top of the printed paste, then pictures were taken under an optical microscope for examining the print quality and slump. After pictures were taken, the sample was placed on the top of a hot plate with temperature settings at 100° C., 150° C., and 200° C. for 5 minutes, respectively. The samples were examined again for slump under an optical microscope with pictures taken.

For each print, 500 printed paste dots were obtained for each pattern.

The slump rate for a given combination of conditions was defined by the equation below.

Np = No. of paste dots after print

Nh = No. of paste dots after hot plate treatment

$$\text{Slump Rate} \text{=} \left(\text{Np} \text{−} \text{Nh}\right) / \text{Np} \times \text{100\%}$$

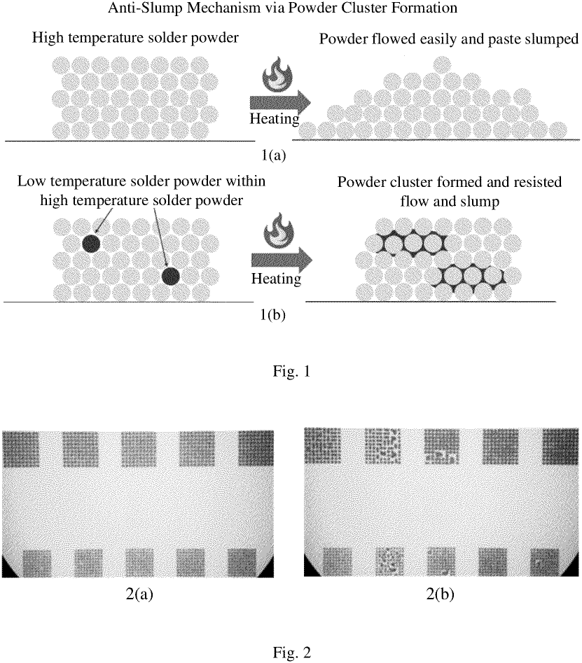

FIG. 2 illustrates SAC solder paste printed with 75 µm thick stencil. As shown in FIG. 2(a), SAC solder paste was printed freshly at room temperature. As shown in FIG. 2(b), SAC solder paste was conditioned on 200° C. hot plate for 5 minutes, slump was observed for the 200° C. heated sample as evidenced by the reduced number of paste dots.

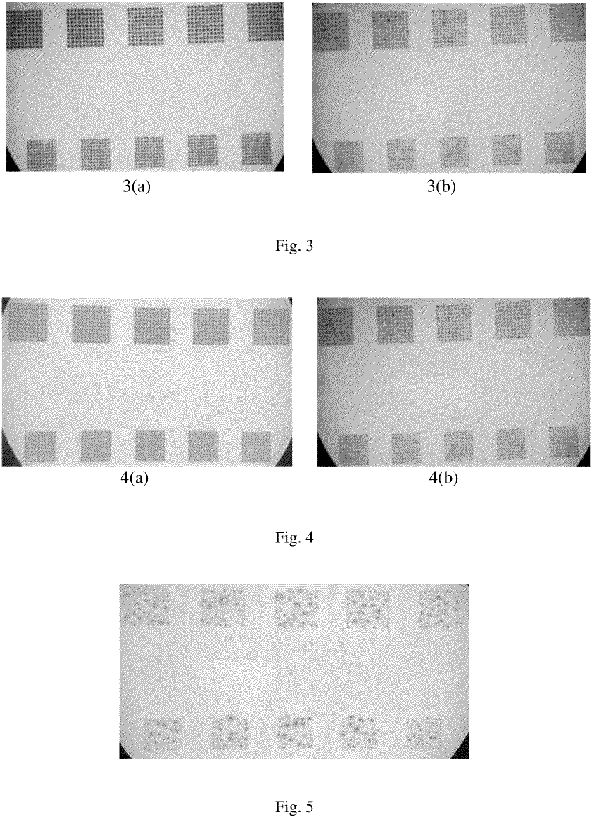

FIG. 3 illustrates B4 solder paste printed with 75 µm thick stencil. As shown in FIG. 3(a), B4 solder paste was printed freshly at room temperature. As shown in FIG. 3(b), B4 solder paste was conditioned on 200° C. hot plate for 5 minutes; slump was resisted for the 200° C. heated sample.

FIG. 4 illustrates I4 solder paste printed with 75 µm thick stencil. As shown in FIG. 4(a), I4 solder paste was printed freshly at room temperature. As shown in FIG. 4(b), I4 solder paste was conditioned on 200° C. hot plate for 5 minutes; slump was resisted for the 200° C. heated sample.

FIG. 5 illustrates B16 solder paste printed with 75 µm thick stencil; for B16 the ratio the mass of the low temperature solder powder is 29.5%, as shown in table 1. When B16 was tested at high temperature, such as 200° C., the bridged paste might have coalesced to form large solder balls. In this case, each ball was counted as a big dot of solder paste in the slump rate determination; as a result, the slump rate increases.

As the ratio the mass of the low temperature solder powder to that of the solder paste (i.e. content of the low temperature solder powder, w/w) increases, for example, exceeding 10%, the slump rate increases as well. However, whatever the content of the low temperature solder powder is not less than either 1% or 10%, the slump rate fundamentally decreased, as compared with prior solder paste, such as a solder paste with a high temperature solder powder while without a low temperature solder powder.

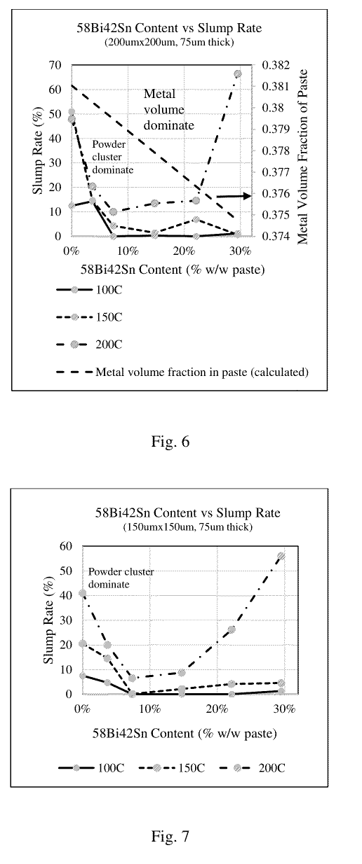

FIG. 6 illustrates effect of 58Bi42Sn content on slump rate when tested on pattern 200 µm × 200 µm, with 75 µm thickness, and the 58Bi42Sn was used as the low temperature solder powder. The slump rate decreased rapidly with increasing 58Bi42Sn content up to about 10%, then increased with a further increase in 58Bi42Sn content. Although the slump rate increased when the 58Bi42Sn content is not less than 10%, the slump rate fundamentally decreased as compared with prior solder paste, such as the sample of SAC shown in table 1.

The initial decrease of the slump rate as described above is attributable to the “powder cluster” effect. This is particularly true when tested at 150° C. and 200° C., where the 58Bi42Sn melted at 138° C. thus was capable of forming powder clusters. The positive effect of the 58Bi42Sn was also noticeable at 100° C. when the 58Bi42Sn had not melted yet. Presumably, at 100° C. the 58Bi42Sn was soft enough to form incipient powder clusters through solid-state diffusion bonding.

The increase in slump rate with increasing 58Bi42Sn content greater than 10% was attributed to the “solder volume” factor. With the solder paste containing 58Bi42Sn having a density higher than SAC solder, the volume fraction of total solder powder in the solder paste decreased with increasing 58Bi42Sn content, as shown in FIG. 6. With decreasing volume fraction of the solder powder, the viscosity decreases and the slump increases.

Therefore, with increasing 58Bi42Sn content, initially the decreasing slump rate was dictated by the powder cluster effect. But the subsequent increasing slump rate trend was caused by a solder volume effect. The solder volume effect was further aggravated by a higher temperature, and consequently resulted in a slump rate being the highest at 200° C., followed by 150° C., with 100° C. rendered the lowest slump rate.

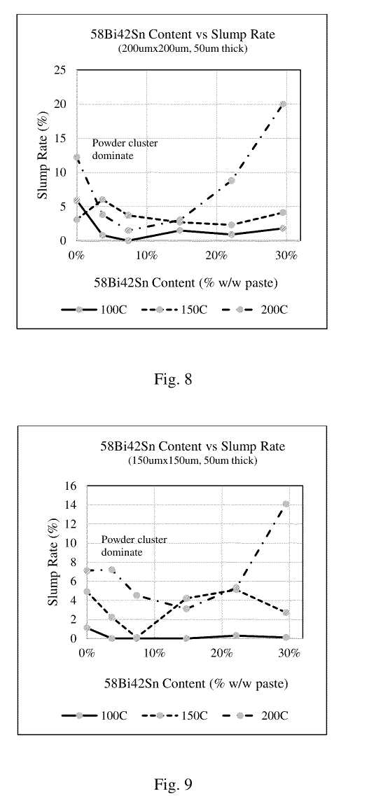

A similar 58Bi42Sn content effect as shown in FIG. 6 was also observed when using a stencil with other combination of aperture dimension and stencil thickness, as shown in FIG. 7 to FIG. 9. Although some data scattering was observed, the trend was very distinct.

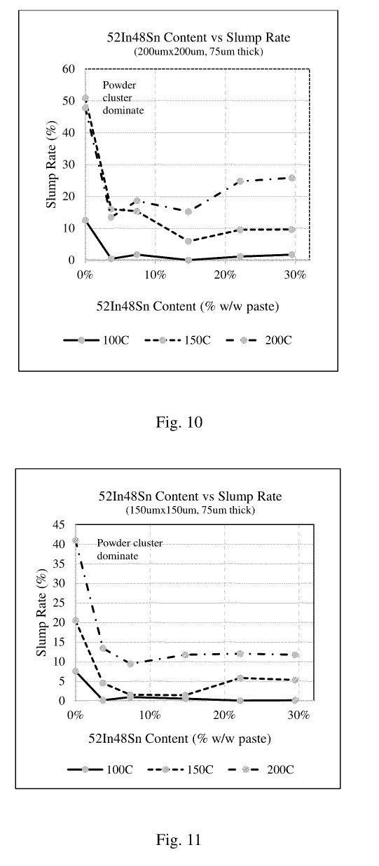

FIG. 10 illustrates effect of 52In48Sn content on slump rate when tested on pattern 200 µm × 200 µm, with 75 µm thickness, and the 52In48Sn was used as the low temperature solder powder. The slump rate decreased rapidly with increasing 52In48Sn content up to about 10% w/w paste, then leveled off with a further increase in 52In48Sn content. The slump rate fundamentally decreased as compared with prior solder paste, such as the sample of SAC shown in table 1.

The initial decrease of the slump rate as described above again is attributable to the “powder cluster” effect. This is particularly true when tested at 150° C. and 200° C., where the 52In48Sn melted at 118° C. thus was capable of forming powder clusters. Similar to 58Bi42Sn case, the positive effect of addition of 52In48Sn was also noticeable at 100° C. when the 52In48Sn had not melted yet. Again, this is attributed to solid-state diffusion bonding of 52In48Sn.

Solder Volume factor observed in the solder paste containing 58Bi42Sn was not observed in the solder paste containing 52In48Sn. This is attributed to the similar density of 52In48Sn (7.3 g/cm3) and SAC305 (7.4 g/cm3).

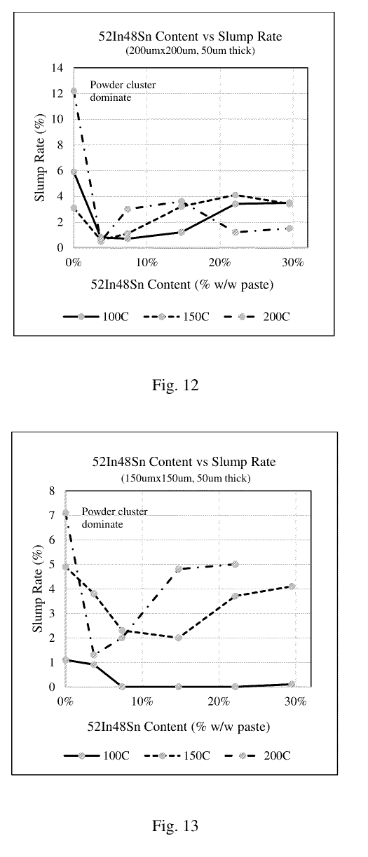

A similar 52In48Sn content effect as shown in FIG. 10 was also observed when using a stencil with other combination of aperture dimension and stencil thickness, as shown in FIG. 11 to FIG. 13. Although some data scattering was observed, particularly in FIG. 13, overall the trend was very distinct.

The solder paste as described herein includes a high temperature solder powder and a low temperature solder powder. The temperature difference between the melting temperatures of the high temperature solder powder and the low temperature solder powder may be no less than 120° C., preferably no less than 90° C., more preferably no less than 50° C.

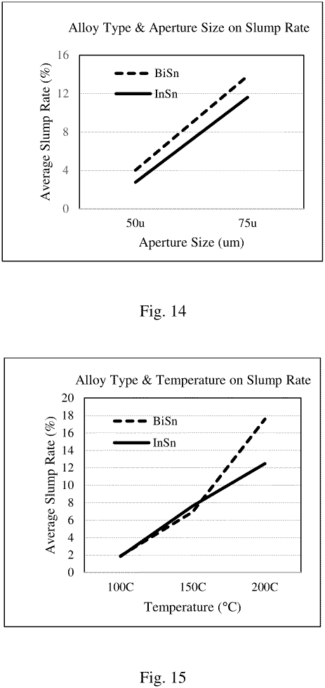

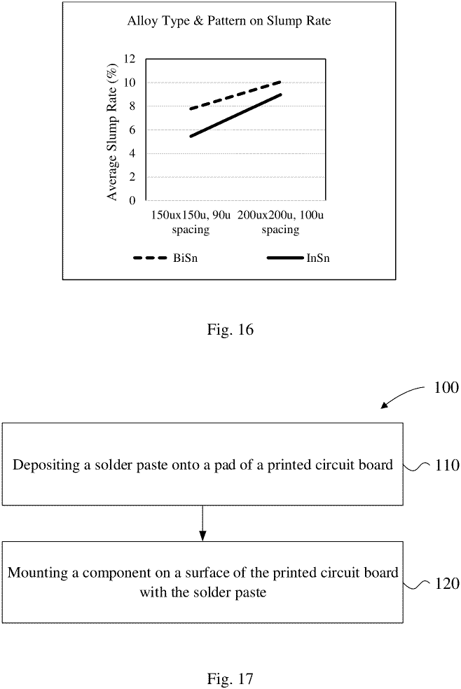

The comparison of slump rate between a solder paste containing 58Bi42Sn and another solder paste containing 52In48Sn is shown in FIGS. 14, 15 and 16. The solder paste containing 52In48Sn showed a measurably lower slump rate than the solder paste containing 58Bi42Sn. This is attributed to the lower melting temperature of 52In48Sn, thus powder cluster was formed at a lower temperature before further slump may be developed at a higher temperature.

SnPb eutectic solder, although lower in melting temperature than SAC solders, has been used by the electronic industry for decades without issue on the service temperature. This indicates the melting temperature of SnPb system is high enough for most applications. To benchmark against 63Sn37Pb (melted at 183° C.) or 62Sn36Pb2Ag (melted at 179° C.) on the service temperature, the 1^{st} sign of melting of the solders should be equal or higher than around 179° C., such a range of temperature from 170° C. to 190° C. Data in Table 1 suggested that sample B2, B4, B8, I2, I4 and I8 would be acceptable choice.

Based on Table 1, to have temperature at 1^{st} sign of melting around 179° C. or higher, the content of low temperature solder powder should be 15% w/w of the solder paste or less for both the solder pastes containing 58Bi42Sn and 52In48Sn.

FIG. 17 illustrates an operational flow diagram depicting an example of a method 100 using the aforesaid solder paste. At operation 110, the solder paste was deposited onto a pad of a printed circuit board. At operation 120, a component was mounted on a surface of a PCB with the solder paste.

The component may be mounted on a surface of a printed circuit board by heating the solder paste. As described herein, heating includes but not limited to reflow soldering.

In implementations, the method 100 comprising: reflow soldering the component to form a solder joint with the solder paste.

In implementations, a temperature at which the solder paste begins endothermic reaction is not less than around 179° C. upon for example reflow soldering.

In implementations, the method 100 comprising: heating the solder paste for a first period in a first range of temperature, where the low temperature solder powder is solid-state diffused surrounding the high temperature solder powder, wherein a temperature within the first range is not less than a predetermined temperature and less than the melting temperature of the low temperature solder powder, the predetermined temperature is less than the melting temperature of the low temperature solder powder and not less than a temperature 15° C. less than the melting temperature of the low temperature solder powder.

In implementations, the first period is greater than 5 seconds, preferably greater than 10 seconds.

In implementations, the method 100 comprising: heating the solder paste for a second period in a second range of temperature, where the low temperature solder powder is melted and formed a powder cluster surrounding the high temperature solder powder, wherein a temperature within the second range is not less than the melting temperature of the low temperature solder powder and less than the melting temperature of the high temperature solder powder.

In implementations, the second period is greater than 5 seconds, preferably greater than 10 seconds.

This written description uses examples to disclose the invention, including the best mode, and also to enable any person skilled in the art to practice the invention, including making and using any devices or systems and performing any incorporated methods. The patentable scope of the invention is defined by the claims, and may include other examples that occur to those skilled in the art. Such other examples are intended to be within the scope of the claims if they have structural elements that do not differ from the literal language of the claims, or if they include equivalent structural elements with insubstantial differences from the literal languages of the claims.

1. A solder paste comprising:
a high temperature solder powder;
a low temperature solder powder, the melting temperature of which is lower than that of the high temperature solder powder; and
flux;
wherein the high temperature solder powder and the low temperature solder powder are both capable of wetting upon heating.

2. The solder paste of claim 1, wherein the high temperature solder powder is 96.5Sn3Ag0.5Cu and the low temperature solder powder is selected from a group of 58Bi42Sn, 52In48Sn, and combinations thereof.

3. The solder paste of claim 1, wherein a ratio of the mass of the low temperature solder powder to that of the solder paste is not less than 1%.

4. The solder paste of claim 1, wherein a ratio of the mass of the low temperature solder powder to that of the solder paste is not less than 10%.

5. The solder paste of claim 3, wherein a ratio of the mass of the low temperature solder powder to that of the solder paste is not greater than 15%.

6. The solder paste of claim 1, wherein temperature difference between the melting temperatures of the high temperature solder powder and the low temperature solder powder is no less than 120° C.

7. The solder paste of claim 1, wherein temperature difference between the melting temperatures of the high temperature solder powder and the low temperature solder powder is no less than 50° C.

8. A method comprising:
depositing a solder paste onto a pad of a printed circuit board;
mounting a component on a surface of the printed circuit board with the solder paste;
wherein the solder paste is of claim 1.

9. The method of claim 8, comprising: reflow soldering the component to form a solder joint with the solder paste.

10. The method of claim 8, wherein a temperature at which the solder paste begins endothermic reaction is not less than around 179° C.

11. The method of claim 8, comprising: heating the solder paste for a first period in a first range of temperature, where the low temperature solder powder is solid-state diffused surrounding the high temperature solder powder, wherein a temperature within the first range is not less than a predetermined temperature and less than the melting temperature of the low temperature solder powder, the predetermined temperature is less than the melting temperature of the low temperature solder powder and not less than a temperature 15° C. less than the melting temperature of the low temperature solder powder.

12. The method of claim 11, wherein the first period is greater than 5 seconds.

13. The method of claim 11, wherein the first period is greater than 10 seconds.

14. The method of claim 8, comprising: heating the solder paste for a second period in a second range of temperature, where the low temperature solder powder is melted and formed a powder cluster surrounding the high temperature solder powder, wherein a temperature within the second range is not less than the melting temperature of the low temperature solder powder and less than the melting temperature of the high temperature solder powder.

15. The method of claim 14, wherein the second period is greater than 5 seconds.

16. The method of claim 14, wherein the second period is greater than 10 seconds.
